(19) United States
(12) Patent Application Publication
(10) Pub. No.: US 2026/0354073 A1
(43) Pub. Date: Nov. 5, 2026

(54) VAPORIZER FOR SUBSTRATE PROCESSING DEVICE AND SUBSTRATE PROCESSING DEVICE

(71) Applicant: JUSUNG ENGINEERING CO., LTD., Gwangju-si, Gyeonggi-do (KR)

(72) Inventors: Won Jin LEE, Yongin-si, Gyeonggi-do (KR); Won Teak JUNG, Yongin-si, Gyeonggi-do (KR); Ji Won JUNG, Yongin-si, Gyeonggi-do (KR); Sun Yong PARK, Yongin-si, Gyeonggi-do (KR); Jin Won KIM, Yongin-si, Gyeonggi-do (KR); Chul Joo HWANG, Yongin-si, Gyeonggi-do (KR)

(21) Appl. No.: 19/474,284

(22) PCT Filed: Mar. 28, 2024
(86) PCT No.: PCT/KR2024/003894

§ 371 Date: Oct. 10, 2025

(30) Foreign Application Priority Data
Apr. 11, 2023 (KR) 10-2023-0047723

(51) Int. Cl. H10P 72/00

(52) U.S. Cl. CPC H10P 72/0402; H10P 72/0421

(57) ABSTRACT

The present invention relates to a vaporizer for a substrate processing device and a substrate processing device, wherein the vaporizer for a substrate processing device comprises: a first inlet into which a liquid or solid precursor and a first carrier gas are supplied; a diffusion unit including a diffusion space wider than the first inlet and diffusing the precursor within the diffusion space; a second inlet connected to the diffusion unit and supplied with a second carrier gas that assists the diffusion of the precursor; and a vaporization unit communicating with the diffusion unit and vaporizing the diffused precursor.

### TECHNICAL FIELD

The present inventive concept relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process on a substrate may be performed by a substrate processing apparatus.

A substrate processing apparatus according to the related art includes a substrate processing unit which performs a processing process on a substrate and a supply unit which supplies a source gas to the substrate processing unit. The supply unit includes a vaporizer which vaporizes a precursor. The supply unit vaporizes the precursor by using the vaporizer to generate a source gas, and then, supplies the source gas to the substrate processing unit. The substrate processing unit performs the processing process by using the source gas supplied from the supply unit.

In the substrate processing apparatus according to the related art, the vaporizer simultaneously performs mixing of a vaporization assistant carrier gas and the supply of heat energy to vaporize the precursor. Therefore, in the related art, because viscosity increases due to heat occurring in a process of vaporizing the precursor, plugging occurs, and due to this, there is a problem where the supply of the source gas is not smoothly performed. Such a problem is more worsened in a case which uses a high-viscosity precursor.

### DISCLOSURE

### Technical Problem

The present inventive concept is devised to solve the above-described problem and is for providing a vaporization apparatus for substrate processing apparatus and a substrate processing apparatus, which may prevent the occurrence of plugging caused by an increase in viscosity in a process of vaporizing a precursor.

### Technical Solution

To accomplish the above-described objects, the present inventive concept may include the following elements.

A vaporization apparatus for substrate processing apparatus according to the present inventive concept may be for vaporizing a liquid or solid precursor to supply to a substrate in a gaseous state and may include: a first inflow unit supplied with the precursor and a first carrier gas; a diffusion unit including a diffusion space which is wider than the first inflow unit and diffusing the precursor in the diffusion space; a second inflow unit connected to the diffusion unit and supplied with a second carrier gas assisting the diffusion of the precursor; and a vaporization unit connecting with the diffusion unit to vaporize the diffused precursor.

In the vaporization apparatus for substrate processing apparatus according to the present inventive concept, the diffusion unit may include a cooling unit for cooling the diffusion space.

In the vaporization apparatus for substrate processing apparatus according to the present inventive concept, the diffusion unit may be controlled at a first temperature. The vaporization unit may be controlled at a second temperature. The first temperature may be lower than the second temperature.

A substrate processing apparatus according to the present inventive concept may include: a supply unit supplying a source gas; and a substrate processing unit performing a processing process on a substrate by using the source gas supplied from the supply unit. The supply unit may include: a first inflow unit supplied with a precursor and a first carrier gas; a diffusion unit including a diffusion space which is wider than the first inflow unit and diffusing the precursor in the diffusion space; a second inflow unit connected to the diffusion unit and supplied with a second carrier gas assisting the diffusion of the precursor; and a vaporization unit connecting with the diffusion unit to vaporize the diffused precursor.

In the substrate processing apparatus according to the present inventive concept, the diffusion unit may include a cooling unit for cooling the diffusion space.

In the substrate processing apparatus according to the present inventive concept, the diffusion unit may be controlled at a first temperature. The vaporization unit may be controlled at a second temperature. The first temperature may be lower than the second temperature.

### Advantageous Effect

According to the present inventive concept, the following effects may be realized. The present inventive concept may prevent the occurrence of plugging caused by an increase in viscosity in a process of vaporizing a precursor. Accordingly, the present inventive concept may enhance the stability of the vaporization of a precursor and the supply of a source gas.

The present inventive concept may prevent the occurrence of plugging even when a source gas is generated by vaporizing a high-viscosity precursor and may thus perform a processing process by using the high-viscosity precursor. Accordingly, the present inventive concept may enhance the quality of a substrate on which a processing process has been performed.

The present inventive concept may prevent the occurrence of plugging even when a source gas is generated by vaporizing a high-viscosity precursor, and thus, may increase a maintenance period caused by the occurrence of plugging and may also reduce the maintenance cost. Accordingly, the present inventive concept may decrease the process cost of a processing process and may thus contribute to decrease the manufacturing cost of a substrate on which a processing process has been performed. Also, the present inventive concept may increase an operating rate to increase the productivity of a substrate on which a processing process has been performed.

The present inventive concept may prevent the occurrence of plugging even when the source gas is generated by vaporizing a high-viscosity precursor, and thus, may increase a flow rate of a precursor supplied to a vaporization unit to increase the amount of production of the source gas. Accordingly, the present inventive concept may increase a flow rate of a source gas supplied to a substrate processing unit, and thus, may more enhance the quality of a substrate on which a processing process has been performed. Also, the present inventive concept may shorten a time taken in a processing process, and thus, may more enhance the productivity of a substrate on which a processing process has been performed.

### DESCRIPTION OF DRAWINGS

FIG. 1 is a schematic configuration diagram of a substrate processing apparatus according to the present inventive concept.

FIG. 2 is a schematic side cross-sectional view of a vaporization apparatus for substrate processing apparatus according to the present inventive concept.

FIG. 3 is a schematic side cross-sectional view illustrating the enlargement of a first inflow unit and a second inflow unit in a substrate processing apparatus according to the present inventive concept.

FIG. 4 is a schematic side cross-sectional view of an injection unit in a substrate processing apparatus according to the present inventive concept.

FIG. 5 is a schematic side cross-sectional view of a modified embodiment of an injection unit in a substrate processing apparatus according to the present inventive concept.

### MODE FOR INVENTIVE CONCEPT

Hereinafter, an embodiment of a substrate processing apparatus according to the present inventive concept will be described in detail with reference to the accompanying drawings. A vaporization apparatus for substrate processing apparatus according to the present inventive concept may be included in a substrate processing apparatus according to the present inventive concept, and thus, will be described together in describing an embodiment of the substrate processing apparatus according to the present inventive concept.

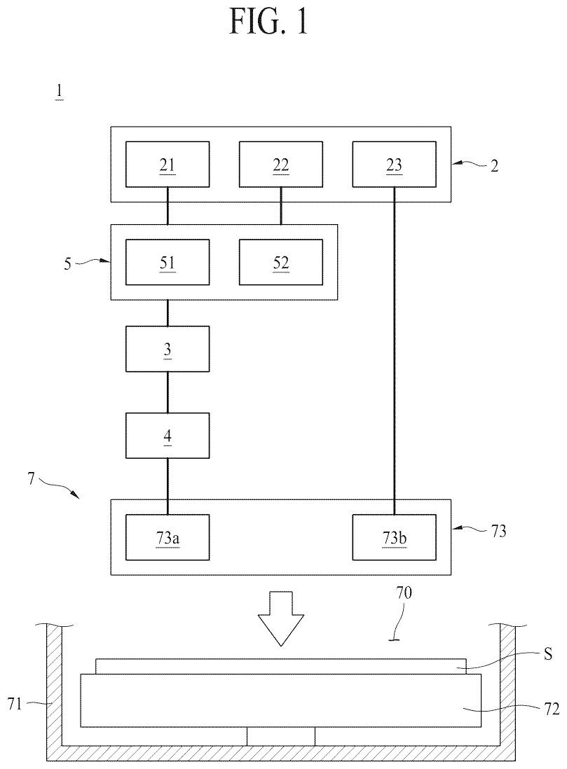

Referring to FIG. 1, a substrate processing apparatus 1 according to the present inventive concept performs a processing process on a substrate S. The substrate S may be a silicon substrate, a glass substrate, a metal substrate, or the like. The substrate processing apparatus 1 according to the present inventive concept may perform a processing process such as a deposition process of depositing a thin film on the substrate S and an etching process of removing a portion of the thin film deposited on the substrate S. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a supply unit 2 which supplies a gas and a substrate processing unit 7 which performs the processing process by using a gas supplied from the supply unit 2.

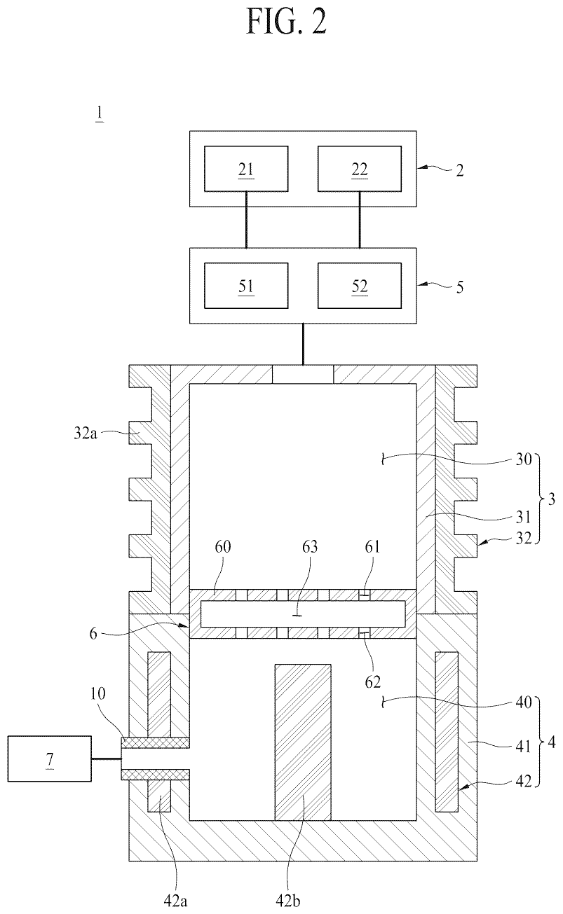

Referring to FIGS. 1 and 2, the supply unit 2 supplies a gas to the substrate processing unit 7. The supply unit 2 may be connected to the substrate processing unit 7 through a hole of a pipe, a hose, or a gas block. The supply unit 2 may be disposed outside the substrate processing unit 7.

The supply unit 2 may supply a source gas to the substrate processing unit 7. In this case, the supply unit 2 may include a diffusion unit 3, a vaporization unit 4, and an inflow unit 5. The diffusion unit 3, the vaporization unit 4, and the inflow unit 5 may be implemented as the vaporization apparatus for substrate processing apparatus according to the present inventive concept.

The supply unit 2 vaporizes a liquid or solid precursor to supply to the substrate S in a gaseous state. The supply unit 2 may vaporize the liquid or solid precursor to generate the source gas. The precursor may include a source material and may be in a liquid state or a solid state. The supply unit 2 may vaporize a liquid-state or solid-state precursor to generate the source gas, and then, may supply a gaseous-state source gas to the substrate processing unit 7.

Referring to FIGS. 1 and 2, the diffusion unit 3 diffuses the precursor supplied from the inflow unit 5. The diffusion unit 3 may be connected to the inflow unit 5. The inflow unit 5 may supply the precursor and a first carrier gas, and in this case, the diffusion unit 3 may diffuse the precursor and the first carrier gas supplied from the inflow unit 5. The first carrier gas is for transferring the precursor, and for example, may include an inert gas. The inflow unit 5 may supply the precursor and the first carrier gas to the diffusion unit 3 together and may supply a second carrier gas to the diffusion unit 3. In this case, the diffusion unit 3 may diffuse the precursor, the first carrier gas, and the second carrier gas supplied from the inflow unit 5. The second carrier gas assists the diffusion of the precursor. The second carrier gas may assist the diffusion of the precursor and may simultaneously assist a flow of the source gas. The second carrier gas may include an inert gas. For example, the second carrier gas may be argon (Ar). In the diffusion unit 3, the precursor and the second carrier gas may be mixed with each other while being diffused. The second carrier gas may be a vaporization assistant gas which assists the vaporization of the precursor.

In the diffusion unit 3, the precursor and the second carrier gas may be diffused at a temperature which is lower than the vaporization unit 4. For example, the precursor and the second carrier gas may be diffused in the diffusion unit 3 having a first temperature and may be vaporized by heat energy in the vaporization unit 4 having a second temperature, and thus, may be generated as the source gas. In this case, the first temperature may be lower than the second temperature. The diffusion unit 3 may be controlled at the first temperature. The vaporization unit may be controlled at the second temperature.

As described above, the substrate processing apparatus 1 according to the present inventive concept is implemented so that the precursor and the second carrier gas are diffused at a relatively low temperature in the diffusion unit 3 and is then vaporized at a relatively high temperature in the vaporization unit 4, and thus, the source gas is generated. That is, the substrate processing apparatus 1 according to the present inventive concept is implemented so that the diffusion of the precursor and the vaporization of the precursor by heat energy are sequentially performed in spaces apart from each other. The substrate processing apparatus 1 according to the present inventive concept may reduce an increase in viscosity occurring in a process of vaporizing the precursor, and thus, may prevent the occurrence of plugging caused by an increase in viscosity. Therefore, the substrate processing apparatus 1 according to the present inventive concept is implemented so that the vaporization of the precursor and the supply of the source gas are smoothly performed. Accordingly, the substrate processing apparatus 1 according to the present inventive concept may realize the following effects.

First, the substrate processing apparatus 1 according to the present inventive concept may prevent the occurrence of plugging even when the source gas is generated by vaporizing a high-viscosity precursor, and thus, may perform the processing process by using the high-viscosity precursor. Accordingly, the substrate processing apparatus 1 according to the present inventive concept may enhance the quality of the substrate S on which the processing process has been performed. For example, the substrate processing apparatus 1 according to the present inventive concept may generate the source gas by using a precursor having high viscosity which is higher than 10 CP (Centi Poise) and may perform the processing process by using the generated source gas.

Second, the substrate processing apparatus 1 according to the present inventive concept may prevent the occurrence of plugging even when the source gas is generated by vaporizing a high-viscosity precursor, and thus, may increase a maintenance period caused by the occurrence of plugging and may also reduce the maintenance cost. Accordingly, the substrate processing apparatus 1 according to the present inventive concept may decrease the process cost of the processing process and may thus contribute to decrease the manufacturing cost of the substrate S on which the processing process has been performed. Also, the substrate processing apparatus 1 according to the present inventive concept may increase an operating rate to increase the productivity of the substrate S on which the processing process has been performed.

Third, the substrate processing apparatus 1 according to the present inventive concept may prevent the occurrence of plugging even when the source gas is generated by vaporizing a high-viscosity precursor, and thus, may increase a flow rate of a precursor supplied to the diffusion unit 3 to increase the amount of production of the source gas. Accordingly, the substrate processing apparatus 1 according to the present inventive concept may increase a flow rate of the source gas supplied to the substrate processing unit 7, and thus, may more enhance the quality of the substrate S on which the processing process has been performed. Also, the substrate processing apparatus 1 according to the present inventive concept may shorten a time taken in the processing process, and thus, may more enhance the productivity of the substrate S on which the processing process has been performed.

Referring to FIGS. 1 and 2, the diffusion unit 3 may include a diffusion space 30.

The diffusion of the precursor may be performed in the diffusion space 30. The diffusion space 30 may be formed to be wider than a first inflow unit 51 included in the inflow unit 5. The first inflow unit 51 supplies the precursor and the first carrier gas. Because the diffusion space 30 is formed to be wider than the first inflow unit 51, the precursor and the first carrier gas may be widely diffused while being supplied from the first inflow unit 51 to the diffusion space 30. Accordingly, the precursor may be smoothly mixed with the second carrier gas while being widely diffused in the diffusion space 30.

Referring to FIGS. 1 and 2, the diffusion unit 3 may include a diffusion body 31.

The diffusion body 31 provides the diffusion space 30. The diffusion body 31 may be adjusted at the first temperature. Therefore, the diffusion and mixing of the precursor and the second carrier gas in the diffusion space 30 may be performed in a state of the first temperature. The first temperature may be a temperature range where the vaporization of the precursor by heat is not performed and the condensation of the precursor is not performed in the diffusion space 30. The first temperature may be previously set by a worker via a previous test. Accordingly, the substrate processing apparatus 1 according to the present inventive concept may reduce an increase in viscosity in a process of diffusing the precursor and the second carrier gas in the diffusion space 30, and thus, may prevent the occurrence of plugging caused by an increase in viscosity.

The diffusion body 31 may be formed in a cylindrical shape where an inner portion is entirely empty, but is not limited thereto and may be formed in another shape such as a rectangular parallelepiped shape capable of providing the diffusion space 30 where the diffusion of the precursor and the second carrier gas may be performed and an inner portion is empty.

Referring to FIGS. 1 and 2, the diffusion unit 3 may include a cooling unit 32.

The cooling unit 32 is coupled to the diffusion body 31. The cooling unit 32 may cool the diffusion space 30. Therefore, even when heat occurring in a process of performing vaporization based on heat energy in the vaporization unit 4 is transferred to the diffusion unit 3, the cooling unit 32 may cool the diffusion space 30 and may thus prevent vaporization based on heat from being performed in the diffusion space 30. Therefore, the cooling unit 32 may reduce an increase in viscosity in a process where the diffusion and mixing of the precursor and the second carrier gas are performed in the diffusion space 30. The cooling unit 32 may cool the diffusion space 30 and may thus maintain the diffusion space 30 at the first temperature.

The cooling unit 32 may include a heat dissipation plate 32a. The heat dissipation plate 32a may be coupled to an outer surface of the diffusion body 31. Therefore, the heat dissipation plate 32a may dissipate heat occurring in the diffusion unit 3 and heat transferred from the vaporization unit 4, and thus, may cool the diffusion space 30. An air cooling path may be applied to the heat dissipation plate 32a. The heat dissipation plate 32a may be coupled to the entire outer surface of the diffusion body 31. Accordingly, the heat dissipation plate 32a may prevent vaporization based on heat from being performed before the precursor disposed in the diffusion space 30 reaches the vaporization unit 4.

Referring to FIGS. 1 and 2, the vaporization unit 4 vaporizes the precursor by using heat energy. The vaporization unit 4 may connect with the diffusion unit 3. Therefore, a precursor diffused in the diffusion unit 3 may be supplied to the vaporization unit 4 and may be vaporized by heat energy. Vaporization based on heat may be performed in the vaporization unit 4 at a temperature which is higher than the diffusion unit 3. For example, the precursor and the second carrier gas may be diffused in the diffusion unit 3 having the first temperature and may then be vaporized by heat energy in the vaporization unit 4 having the second temperature, and thus, the source gas may be generated. In this case, the second temperature may be higher than the first temperature.

As described above, the substrate processing apparatus 1 according to the present inventive concept may be implemented so that the diffusion of the precursor is performed in the diffusion unit 3, and then, the vaporization of the precursor by heat energy is performed in the vaporization unit 4. Therefore, the substrate processing apparatus 1 according to the present inventive concept may reduce an increase in viscosity occurring in a process of vaporizing the precursor and may thus prevent the occurrence of plugging caused by an increase in viscosity. Accordingly, the substrate processing apparatus 1 according to the present inventive concept is implemented so that the vaporization of the precursor and the supply of the source gas are smoothly performed.

The vaporization unit 4 may include a vaporization body 41 and a heating unit 42.

The vaporization body 41 provides a vaporization space 40. The vaporization of the precursor by heat energy may be performed in the vaporization space 40. The source gas may be generated through the vaporization of the precursor in the vaporization space 40. The vaporization of the precursor may be performed in a state where the vaporization space 40 is at the second temperature. The second temperature may be a temperature range where the vaporization of the precursor by heat is performed in the vaporization space 40. The second temperature may be previously set by a worker via a previous test.

The vaporization body 41 may be coupled to the diffusion body 31. In this case, the vaporization space 40 and the diffusion space 30 may connect with each other. The vaporization body 41 and the diffusion body 31 may be formed as one body. The vaporization body 41 may be formed in a cylindrical shape where an inner portion is entirely empty, but is not limited thereto and may be formed in another shape such as a rectangular parallelepiped capable of providing the vaporization space 40 where an inner portion is empty and the vaporization of the precursor is performed.

The heating unit 42 is coupled to the vaporization body 41. The heating unit 42 may heat the vaporization space 40. Therefore, the heating unit 42 may heat the vaporization space 40 to provide heat energy and may thus allow the vaporization of the precursor by heat to be performed in the vaporization space 40. The heating unit 42 may heat the vaporization space 40 and may thus maintain the vaporization space 40 at the second temperature.

The heating unit 42 may include a first heater 322a.

The first heater 332a is disposed at a sidewall of the vaporization body 41. The first heater 322a may emit heat at the sidewall of the vaporization body 41 and may thus heat the vaporization space 40. The first heater 322a may be disposed to surround the vaporization space 40. Therefore, the first heater 322a may be implemented to entirely emit uniform heat in the vaporization space 40, and thus, may entirely heat the vaporization space 40 at a uniform temperature. The first heater 322a may be disposed to be buried in the sidewall of the vaporization body 41. The first heater 322a may heat the vaporization space 40 through heat emission, heating light emission, and heating medium circulation using electricity.

The second heater 332b is disposed in the vaporization space 40 in an inner portion of the vaporization body 41. The second heater 322b may emit heat of the vaporization body 41 and may thus heat the vaporization space 40. Therefore, the vaporization space 40 may be heated by the first heater 322a disposed at an outer side and the second heater 322b disposed at an inner side. Therefore, the heating unit 42 may enhance the uniformity of a temperature of the vaporization space 40 and may thus enhance the quality of the source gas vaporized by heat energy. The second heater 322b may heat the vaporization space 40 through heat emission, heating light emission, and heating medium circulation using electricity.

The second heater 322b may be disposed at a center of the vaporization space 40. Therefore, the second heater 322b may be disposed to entirely emit uniform heat in the vaporization space 40. For example, in a case where the vaporization space 40 is formed in an entirely cylindrical shape, the second heater 322b may be disposed in a virtual line which connects, with each other, centers of circles configuring a lower surface and an upper surface of a cylinder. One side of the second heater 322b may be coupled to a floor surface of the vaporization body 41, and the other side thereof may be disposed at a position apart from the floor surface of the vaporization body 41. The other side of the second heater 322b may be disposed at a position apart from an upper surface of the vaporization body 41. The upper surface of the vaporization body 41 may be a portion which is connected to the diffusion body 31. Therefore, the vaporization body 41 may be disposed not to prevent the diffused precursor from flowing in from the diffusion body 31. The other side of the second heater 322b may be disposed apart from the upper surface of the vaporization body 41 by a distance which is shorter than the floor surface of the vaporization body 41.

The supply unit 2 may include a discharge portion 10. The discharge portion 10 may be coupled to the vaporization body 41. One side of the discharge portion 10 may connect with the vaporization space 40. The other side of the discharge portion 10 may be connected to the substrate processing unit 7. Therefore, the source gas generated by the vaporization of the precursor in the vaporization space 40 may be supplied to the substrate processing unit 7 through the discharge portion 10. The other side of the discharge portion 10 may be connected to the substrate processing unit 7 through a hole of a pipe, a hose, or a gas block.

Referring to FIGS. 1 to 3, the inflow unit 5 supplies the precursor, the first carrier gas, and the second carrier gas to the diffusion unit 3. The inflow unit 5 may be coupled to the diffusion unit 3. As the precursor and the second carrier gas are diffused in the diffusion unit 3 at a temperature which is lower than the vaporization unit 4, an increase in viscosity may be reduced, and thus, the inflow unit 5 may supply a high-viscosity precursor to the diffusion unit 3.

The inflow unit 5 may be coupled to the diffusion body 31 to connect with the diffusion space 30. The diffusion body 31 may be disposed between the inflow unit 5 and the vaporization body 41. In a case where the vaporization body 41 is coupled to a lower portion of the diffusion body 31, the inflow unit 5 may be coupled to an upper portion of the diffusion body 31.

The inflow unit 5 may include the first inflow unit 51 and a second inflow unit 52.

The first inflow unit 51 may supply the precursor and the first carrier gas. The precursor and the first carrier gas may be supplied to the diffusion unit 3 through the first inflow unit 51. The diffusion unit 3 may include the diffusion space 30 which is wider than the first inflow unit 51. Accordingly, the substrate processing apparatus 1 according to the present inventive concept may more increase a diffusion force of the precursor in the diffusion unit 3. In this case, a mixing ratio between the precursor and the second carrier gas in the diffusion unit 3 may increase.

The first inflow unit 51 may be connected to a first supply mechanism 21. The first supply mechanism 21 supplies the precursor and the first carrier gas. The first supply mechanism 21 may be connected to the first inflow unit 51 through a hole of a pipe, a hose, or a gas block. Although not shown, the first supply mechanism 21 may include a first storage tank which stores the precursor, a first pump which supplies the first carrier gas to the first storage tank, and a first valve for selectively supplying the precursor.

The first inflow unit 51 may supply a precursor having high viscosity, which is higher than 10 CP, to the diffusion unit 3. Even when the precursor having high viscosity which is higher than 10 CP is supplied by the first inflow unit 51, the substrate processing apparatus 1 according to the present inventive concept may reduce an increase in viscosity occurring in a process of vaporizing the precursor and may thus prevent the occurrence of plugging, whereby a source gas generated by using a high-viscosity precursor may be smoothly supplied to the substrate processing unit 7. Accordingly, the substrate processing apparatus 1 according to the present inventive concept may smoothly perform the processing process by using a high-viscosity precursor, and thus, may more enhance the quality of a substrate on which the processing process has been performed and may also shorten a time taken in the processing process to more enhance the productivity of a substrate on which the processing process has been performed.

The second inflow unit 52 may supply the second carrier gas. The second carrier gas may be supplied to the diffusion unit 3 through the second inflow unit 52. The second inflow unit 52 may be connected to a second supply mechanism 22. The second supply mechanism 22 supplies the second carrier gas. The second supply mechanism 22 may be connected to the second inflow unit 52 through a hole of a pipe, a hose, or a gas block. Although not shown, the second supply mechanism 22 may include a second storage tank which stores the second carrier gas, a second pump which supplies the second carrier gas stored in the second storage tank, and a second valve for selectively supplying the second carrier gas.

The inflow unit 5 may include a first nozzle body 53 and a second nozzle body 54.

The first nozzle body 53 is for supplying the precursor and the first carrier gas to the diffusion unit 3. The first nozzle body 53 may include a first supply hole 531. The precursor and the first carrier gas supplied from the first supply mechanism 21 may be supplied to the diffusion space 30 through the first supply hole 531. The first supply hole 531 and the first nozzle body 53 may be included in the first inflow unit 51.

The second nozzle body 54 is disposed apart from the first nozzle body 53 to the outside of the first nozzle body 53. The second nozzle body 54 may be disposed to surround the first nozzle body 53 at a position apart from an outer side of the first nozzle body 53. A space which is formed as the second nozzle body 54 and the first nozzle body 53 are disposed apart from each other may be implemented as a second supply hole 541. The second carrier gas may be supplied to the diffusion unit 3 through the second supply hole 541. In this case, the second carrier gas may be supplied from the second supply mechanism 22 to the inflow unit 5, and then, may be supplied to the diffusion space 30 through the second supply hole 541. Therefore, the second carrier gas supplied through the second supply hole 541 and the precursor and the first carrier gas supplied through the first supply hole 531 may be mixed with one another while being diffused in the diffusion space 30. In this case, the second supply hole 541 and the first supply hole 531 may be implemented to be spatially separated from each other, and thus, the second carrier gas may be prevented from being mixed with the precursor and the first carrier gas until being supplied to the diffusion space 30. The second supply hole 541 and the second nozzle body 54 may be included in the second inflow unit 52.

Referring to FIGS. 1 and 2, the supply unit 2 may include a connection nozzle 6.

The connection nozzle 6 is disposed between the diffusion unit 3 and the vaporization unit 4. The connection nozzle 6 may divide the diffusion space 30 and the vaporization space 40. Therefore, the diffusion of the precursor and the vaporization of the precursor may be performed in spaces apart from each other. The connection nozzle 6 may be disposed in the diffusion body 31 and the vaporization body 41. The connection nozzle 6 may be disposed on a coupling surface where the diffusion body 31 and the vaporization body 41 are coupled to each other.

The connection nozzle 6 may include a plurality of first connection holes 61, a plurality of second connection holes 62, and a connection space 63.

The first connection holes 61 connect with the diffusion space 30. The first connection holes 61 may be formed to pass through the connection body 60. The connection body 60 configures an entire external appearance of the connection nozzle 6. The connection body 60 may be disposed in the diffusion body 31 and the vaporization body 41 and may divide the diffusion space 30 and the vaporization space 40. The first connection holes 61 may be formed to pass through one surface of the connection body 60 facing the diffusion space 30. The first connection holes 61 may be disposed apart from one another.

The second connection holes 62 connect with the vaporization space 40. The second connection holes 62 may be formed to pass through the connection body 60. The second connection holes 62 may be formed to pass through the other surface of the connection body 60 facing the vaporization space 40. The second connection holes 62 may be disposed apart from one another.

The connection space 63 is disposed between the first connection holes 61 and the second connection holes 62. The connection space 63 may correspond to an internal space of the connection body 60. The connection space 63 may connect with the diffusion space 30 through the first connection holes 61 and may connect with the vaporization space 40 through the second connection holes 62. Therefore, the precursor and the second carrier gas may be primarily diffused by the diffusion unit 3 and may then be secondarily diffused by the connection nozzle 6, and thus, may be supplied to the vaporization space 40. Therefore, the connection nozzle 6 may allow the primarily diffused precursor to be supplied to the vaporization space 40 without being bound in the diffusion space 30. This is because a particle of the primarily diffused precursor is divided to have a diameter corresponding to a diameter of each of the first connection holes 61 and the second connection holes 62 while passing through the connection nozzle 6. The diameter of each of the first connection holes 61 and the second connection holes 62 may be formed to be less than a diameter of the particle of the primarily diffused precursor. Accordingly, the substrate processing apparatus 1 according to the present inventive concept may more decrease a diameter of a particle of a precursor supplied to the vaporization space 40 by using the connection nozzle 6, and thus, may allow the vaporization of the precursor to be more smoothly performed in the vaporization space 40.

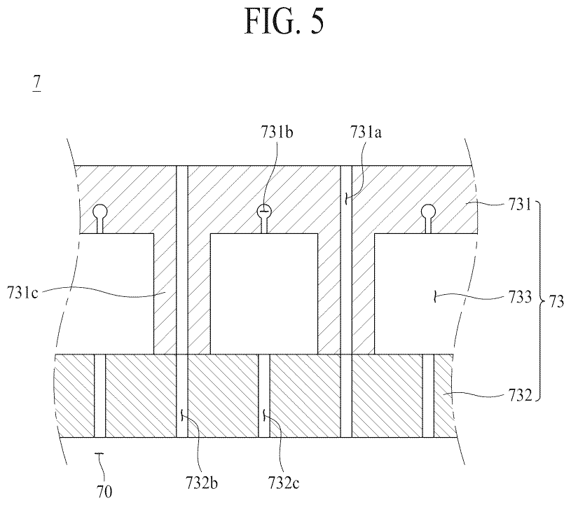

Referring to FIGS. 1 to 5, the substrate processing unit 7 performs the processing process by using a source gas supplied from the supply unit 2. The substrate processing unit 7 may be connected to the vaporization unit 4 and may be supplied with the source gas from the vaporization unit 4. The substrate processing unit 7 may include a chamber 71, a substrate supporting unit 72, and an injection unit 73.

The chamber 71 provides the processing space 70. The processing process may be performed in the processing space 70. The processing space 70 may be disposed in the chamber 71. An exhaust port (not shown) which exhausts a gas from the processing space 70 may be coupled to the chamber 71. The substrate supporting unit 72 and the injection unit 73 may be disposed in the chamber 71.

The substrate supporting unit 72 supports the substrate S. The substrate supporting unit 72 may support one substrate S, or may support a plurality of substrates S. In a case where the plurality of substrates S are supported by the substrate supporting unit 72, a processing process on the plurality of substrates S may be performed at a time. The substrate supporting unit 72 may be coupled to the chamber 71. The substrate supporting unit 72 may be disposed in the chamber 71.

The injection unit 73 injects a gas toward the substrate supporting unit 72. The injection unit 73 may be connected to the supply unit 2. In this case, the injection unit 73 may inject a gas, supplied from the supply unit 2, toward the substrate supporting unit 72. The injection unit 73 may be disposed in the chamber 71. The injection unit 73 may be disposed to be opposite to the substrate supporting unit 72. The injection unit 73 may be disposed on the substrate supporting unit 72. The processing space 70 may be disposed between the injection unit 73 and the substrate supporting unit 72. The injection unit 73 may be coupled to a lid (not shown). The lid may be coupled to the chamber 71 to cover an upper portion of the chamber 71.

The injection unit 73 may include a first gas flow path 73a and a second gas flow path 73b.

The first gas flow path 73a is for injecting a gas. One side of the first gas flow path 73a may be connected to the supply unit 2 through a hole of a pipe, a hose, or a gas block. The other side of the first gas flow path 73a may connect with the processing space 70. Accordingly, a first gas supplied from the supply unit 2 may flow along the first gas flow path 73a, and then, may be injected into the processing space 70 through the first gas flow path 73a. The first gas flow path 73a may function as a flow path for enabling a gas to flow and may function as an injection port for injecting the gas into the processing space 70.

The second gas flow path 73b is for injecting a second gas. The second gas and the first gas may be different gases. For example, when the first gas is a source gas, the second gas may be a reactant gas. One side of the second gas flow path 73b may be connected to the supply unit 2 through a hole of a pipe, a hose, or a gas block. The other side of the second gas flow path 73b may connect with the processing space 70. Accordingly, the second gas supplied from the supply unit 2 may flow along the second gas flow path 73b, and then, may be injected into the processing space 70 through the second gas flow path 73b. The second gas flow path 73b may function as a flow path for enabling the second gas to flow and may function as an injection port for injecting the second gas into the processing space 70.

Furthermore, when the first gas is the source gas, the first gas flow path 73a may be connected to the vaporization unit 4. When the second gas is the reactant gas, the second gas flow path 73b may be connected to a third supply mechanism 23 included in the supply unit 2. The third supply mechanism 23 may be connected to the second gas flow path 73b through a hole of a pipe, a hose, or a gas block. Although not shown, the third supply mechanism 23 may include a third storage tank which stores the reactant gas, a third pump which supplies the reactant gas stored in the third storage tank, and a third valve for selectively supplying the reactant gas.

The second gas flow path 73b and the first gas flow path 73a may be disposed to be spatially separated from each other. Therefore, the second gas supplied from the supply unit 2 to the second gas flow path 73b may be injected into the processing space 70 without passing through the first gas flow path 73a. The first gas supplied from the supply unit 2 to the first gas flow path 73a may be injected into the processing space 70 without passing through the second gas flow path 73b. The second gas flow path 73b and the first gas flow path 73a may inject a gas toward different portions of the processing space 70.

For example, as illustrated in FIG. 2, the injection unit 73 may include a first plate 731 and a second plate 732.

The first plate 731 is disposed on the second plate 732. The first plate 731 and the second plate 732 may be disposed apart from each other. A plurality of first gas holes 731a may be formed in the first plate 731. Each of the first gas holes 731a may function as a path for enabling the first gas to flow. The first gas holes 731a may be included in the first gas flow path 73a. A plurality of second gas holes 731b may be formed in the first plate 731. Each of the second gas holes 731b may function as a path for enabling the second gas to flow. The second gas holes 731b may be included in the second gas flow path 73b. A plurality of protrusion members 731c may be coupled to the first plate 731. The protrusion members 731c may protrude toward the second plate 732 from a lower surface of the first plate 731. Each of the first gas holes 731a may be formed to pass through the first plate 731 and the protrusion member 731c. Although not shown, the lower surface of the first plate 731 may be formed to be flat without the protrusion member 731c.

A plurality of openings 732a may be formed in the second plate 732. The openings 732a may be formed to pass through the second plate 732. The openings 732a may be disposed at positions respectively corresponding to the protrusion members 731c. Therefore, as illustrated in FIG. 2, the protrusion members 731c may be formed by a length which enables the protrusion members 731c to be respectively inserted into the openings 732a. Although not shown, the protrusion members 731c may be formed by a length which enables the protrusion members 731c to be respectively disposed on the openings 732a. The protrusion members 731c may be formed by a length which protrudes downward from the second plate 732. The second gas holes 731b may be disposed to inject a gas toward an upper surface of the second plate 732.

The injection unit 73 may generate plasma by using the second plate 732 and the first plate 731. In this case, a plasma power such as radio frequency (RF) power may be applied to the first plate 731, and the second plate 732 may be grounded. The first plate 731 may be grounded, and the plasma power may be applied to the second plate 732.

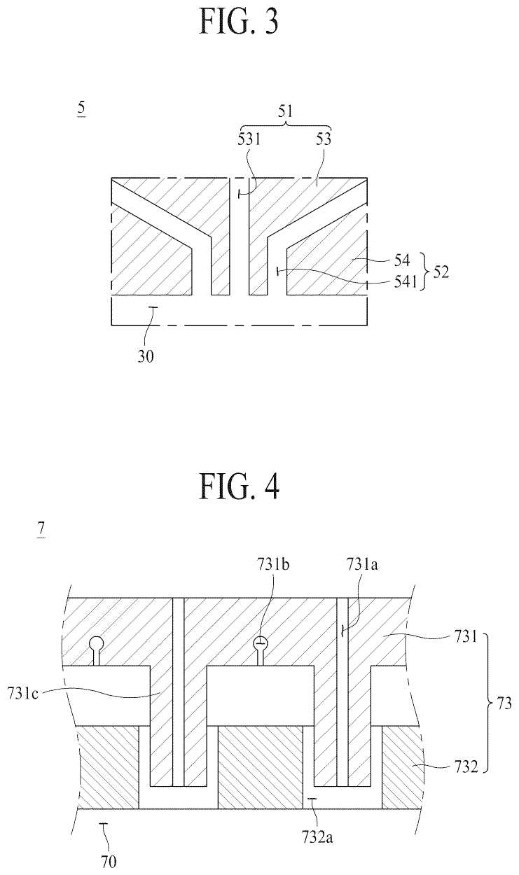

As illustrated in FIG. 3, a plurality of first openings 732b and a plurality of second openings 732c may be formed in the second plate 732.

The first openings 732b may be formed to pass through the second plate 732. The first openings 732b may be respectively connected to the first gas holes 731a. In this case, the protrusion members 731c may be disposed to contact an upper surface of the second plate 732. The first gas may be injected into the processing space 70 via the first gas holes 731a and the first openings 732b. The first gas holes 731a and the first openings 732b may be included in the first gas flow path 73a.

The second openings 732c may be formed to pass through the second plate 732. The second openings 732c may be connected to a buffer space 733 disposed between the first plate 731 and the second plate 732. The second gas may be injected into the processing space 70 via the second gas holes 731b, the buffer space 733, and the second openings 732c. The second gas holes 731b, the buffer space 733, and the second openings 732c may be included in the second gas flow path 73b.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A vaporization apparatus for substrate processing apparatus for vaporizing a liquid or solid precursor to supply to a substrate in a gaseous state, the vaporization apparatus comprising:
a first inflow unit supplied with the precursor and a first carrier gas;
a diffusion unit including a diffusion space which is wider than the first inflow unit and diffusing the precursor in the diffusion space;
a second inflow unit connected to the diffusion unit and supplied with a second carrier gas assisting the diffusion of the precursor; and
a vaporization unit connecting with the diffusion unit to vaporize the diffused precursor,
wherein the diffusion unit comprises a cooling unit for cooling the diffusion space.

2. The vaporization apparatus of claim 1, wherein,
the diffusion unit comprises a diffusion body providing the diffusion space where the precursor and the second carrier gas are diffused, and
the cooling unit is coupled to the diffusion body and cools the diffusion space so that the vaporization of the precursor is prevented in the diffusion space.

3. A vaporization apparatus for substrate processing apparatus for vaporizing a liquid or solid precursor to supply to a substrate in a gaseous state, the vaporization apparatus comprising:
a first inflow unit supplied with the precursor and a first carrier gas;
a diffusion unit including a diffusion space which is wider than the first inflow unit and diffusing the precursor in the diffusion space;
a second inflow unit connected to the diffusion unit and supplied with a second carrier gas assisting the diffusion of the precursor; and
a vaporization unit connecting with the diffusion unit to vaporize the diffused precursor,
wherein,
the diffusion unit is controlled at a first temperature,
the vaporization unit is controlled at a second temperature, and
the first temperature is lower than the second temperature.

4. The vaporization apparatus of claim 3, wherein,
the diffusion unit comprises a diffusion body providing the diffusion space where the precursor and the second carrier gas are diffused, and a cooling unit coupled to the diffusion body, and
the cooling unit cools the diffusion space so that the vaporization of the precursor is prevented in the diffusion space.

5. The vaporization apparatus of claim 4, wherein the cooling unit comprises a heat dissipation unit coupled to an outer surface of the diffusion body.

6. The vaporization apparatus of claim 1, wherein,
the vaporization unit comprises a vaporization body providing a vaporization space where vaporization based on heat energy is performed, and a heating unit coupled to the vaporization body, and
the heating unit heats the vaporization space to provide heat energy.

7. The vaporization apparatus of claim 6, wherein the heating unit comprises a first heater disposed at a sidewall of the vaporization body, and a second heater disposed in the vaporization space in the vaporization body.

8. The vaporization apparatus of claim 1, further comprising a connection nozzle disposed between the diffusion unit and the vaporization unit to divide the diffusion space and a vaporization space of the vaporization unit,
wherein,
the connection nozzle comprises a plurality of first connection holes connecting with the diffusion space, a plurality of second connection holes connecting with the vaporization space, and a connection space disposed between the first connection holes and the second connection holes, and
the precursor is supplied to the vaporization space via the connection space from the diffusion space.

9. The vaporization apparatus of claim 1, wherein,
the first inflow unit comprises a first nozzle body where a first supply hole for supplying the precursor to the diffusion unit is formed,
the second inflow unit comprises a second nozzle body disposed apart from the first nozzle body to an outer side of the first nozzle body, and
the second carrier gas is supplied to the diffusion unit through a second supply hole between the first nozzle body and the second nozzle body.

10. A substrate processing apparatus comprising:
a supply unit supplying a source gas; and
a substrate processing unit performing a processing process on a substrate by using the source gas supplied from the supply unit,
wherein the supply unit comprises:
a first inflow unit supplied with a precursor and a first carrier gas;
a diffusion unit including a diffusion space which is wider than the first inflow unit and diffusing the precursor in the diffusion space;
a second inflow unit connected to the diffusion unit and supplied with a second carrier gas assisting the diffusion of the precursor; and
a vaporization unit connecting with the diffusion unit to vaporize the diffused precursor, and
wherein the diffusion unit comprises a cooling unit for cooling the diffusion space.

11. A substrate processing apparatus comprising:
a supply unit supplying a source gas; and
a substrate processing unit performing a processing process on a substrate by using the source gas supplied from the supply unit,
wherein the supply unit comprises:
a first inflow unit supplied with a precursor and a first carrier gas;
a diffusion unit including a diffusion space which is wider than the first inflow unit and diffusing the precursor in the diffusion space;
a second inflow unit connected to the diffusion unit and supplied with a second carrier gas assisting the diffusion of the precursor; and
a vaporization unit connecting with the diffusion unit to vaporize the diffused precursor,
wherein,
the diffusion unit is controlled at a first temperature,
the vaporization unit is controlled at a second temperature, and
the first temperature is lower than the second temperature.

12. The substrate processing apparatus of claim 11, wherein the diffusion unit comprises a cooling unit for cooling the diffusion space.

13. The substrate processing apparatus of claim 10, wherein,
the vaporization unit comprises a vaporization body providing a vaporization space where vaporization based on heat energy is performed, and a heating unit coupled to the vaporization body, and
the heating unit heats the vaporization space to provide heat energy.

14. The substrate processing apparatus of claim 13, wherein the heating unit comprises a first heater disposed at a sidewall of the vaporization body, and a second heater disposed in the vaporization space in the vaporization body.

15. The substrate processing apparatus of claim 11, wherein,
the supply unit comprises a connection nozzle disposed between the diffusion unit and the vaporization unit to divide the diffusion space and a vaporization space of the vaporization unit,
the connection nozzle comprises a plurality of first connection holes connecting with the diffusion space, a plurality of second connection holes connecting with the vaporization space, and a connection space disposed between the first connection holes and the second connection holes, and
the precursor is supplied to the vaporization space via the connection space from the diffusion space.
